(19) United States
(12) Patent Application Publication
(10) Pub. No.: US 2011/0297431 A1
(43) Pub. Date: Dec. 8, 2011

(54) CONNECTION STRUCTURE

(75) Inventor: Masao Yamada, Kariya-city (JP)

(73) Assignee: DENSO CORPORATION, Kariya-city (JP)

(21) Appl. No.: 13/112,267

(22) Filed: May 20, 2011

(30) Foreign Application Priority Data
Jun. 4, 2010 (JP) 2010-129057
Sep. 2, 2010 (JP) 2010-197039

(51) Int. Cl. H05K 1/05

(52) U.S. Cl. 174/258

(57) ABSTRACT

A connection structure includes a circuit board and a terminal. The circuit board includes an insulation base member containing thermoplastic resin, and a wiring portion arranged in the insulation base member. The wiring portion has a conductor pattern and an interlayer connector electrically connected to the conductor pattern. The terminal is electrically connected to a part of the wiring portion, and has a first section arranged inside of the insulation base member. The first section of the terminal is tightly contact with the thermoplastic resin of the insulation base member, such that the terminal is connected to the circuit board.

### CROSS REFERENCE TO RELATED APPLICATION

This application is based on Japanese Patent Application No. 2010-129057 filed on Jun. 4, 2010 and Japanese Patent Application No. 2010-197039 filed on Sep. 2, 2010, the disclosures of which are incorporated herein by reference in their entirety.

### BACKGROUND OF THE INVENTION

1. Field of the Invention

The present invention relates to a connection structure between a circuit board and a terminal.

2. Description of Related Art

JP-A-2003-214340 describes a connection structure using an elastic member.

A terminal and a circuit board are electrically connected with each other through the elastic member. The elastic member is made of material having small electric resistance, and has a tip end electrically connected to the circuit board. The circuit board is electrically connected to the terminal by inserting the terminal into the elastic member. Because the elastic member is elastically fitted with the terminal, reliability of electric connection between the circuit board and the terminal can be raised.

However, the elastic member causes an increase in the number of components included in a structure.

### SUMMARY OF THE INVENTION

In view of the foregoing and other problems, it is an object of the present invention to provide a connection structure.

According to an example of the present invention, a connection structure includes a circuit board and a terminal made of metal material. The circuit board includes an insulation base member containing thermoplastic resin, and a wiring portion arranged inside of the insulation base member. The wiring portion has a conductor pattern and an interlayer connector. At least a part of the interlayer connector is electrically connected to the conductor pattern. A part of the terminal is arranged inside of the insulation base member. The terminal arranged inside of the insulation base member is electrically connected to a part of the wiring portion, and is tightly contact with the thermoplastic resin of the insulation base member, such that the terminal is connected to the circuit board.

Accordingly, the terminal can be connected to the circuit board without a connector.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross-sectional view illustrating a connection structure according to an embodiment of the present invention;

FIG. 2 is an exploded view of FIG. 1 illustrating a method of producing the connection structure;

FIG. 3 is a cross-sectional view illustrating a connection structure according to a first modification of the embodiment;

FIG. 4 is a cross-sectional view illustrating a connection structure according to a second modification of the embodiment;

FIG. 5 is a cross-sectional view illustrating a connection structure according to a third modification of the embodiment;

FIG. 6 is a cross-sectional view taken along line VI-VI of FIG. 5;

FIG. 7 is a cross-sectional view illustrating a connection structure according to a fourth modification of the embodiment;

FIG. 8 is a cross-sectional view taken along line VIII-VIII of FIG. 7;

FIG. 9 is a cross-sectional view illustrating a connection structure according to a fifth modification of the embodiment;

FIG. 10 is a cross-sectional view illustrating a connection structure according to a sixth modification of the embodiment;

FIG. 11 is a cross-sectional view illustrating a connection structure according to a seventh modification of the embodiment;

FIG. 12A is a cross-sectional view illustrating a connection structure according to an eighth modification of the embodiment, and FIG. 12B is a cross-sectional view illustrating a connection structure according to an eighth modification of the embodiment;

FIG. 13 is a cross-sectional view illustrating a connection structure according to a ninth modification of the embodiment;

FIG. 14 is a cross-sectional view illustrating a connection structure according to a tenth modification of the embodiment;

FIG. 15 is a cross-sectional view illustrating a connection structure according to an eleventh modification of the embodiment;

FIG. 16 is a perspective view illustrating the connection structure of the eleventh modification;

FIG. 17 is a perspective view illustrating a connection structure according to a twelfth modification of the embodiment;

FIG. 18 is a cross-sectional view illustrating a connection structure according to a thirteenth modification of the embodiment;

FIG. 19 is a cross-sectional view illustrating a connection structure according to a fourteenth modification of the embodiment;

FIG. 20 is a cross-sectional view illustrating a connection structure according to a fifteenth modification of the embodiment;

FIGS. 21A-21E are side views respectively illustrating a terminal of a connection structure according to a sixteenth modification of the embodiment;

FIG. 22 is a side view illustrating a terminal of a connection structure according to a seventeenth modification of the embodiment; and

FIGS. 23A-23E are side views respectively illustrating a terminal of a connection structure according to an eighteenth modification of the embodiment.

### DETAILED DESCRIPTION OF PREFERRED EMBODIMENT

### Embodiment

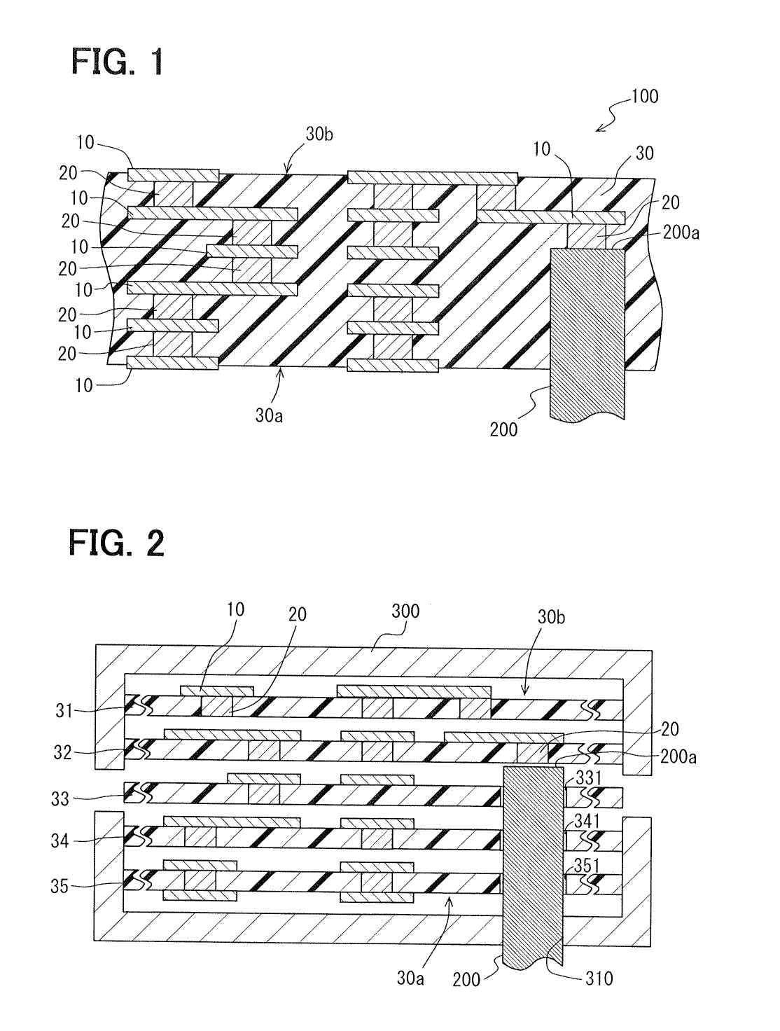

An embodiment will be described with reference to FIGS. 1 and 2.

As shown in FIG. 1, a circuit board 100 includes an insulation base member 30, and a wiring portion having a conductor pattern 10 and an interlayer connector 20. The conductor pattern 10 is multi-layered in the base member 30. That is, a plurality of the conductor patterns 10 is layered through the base member 30 in a layering direction. The layering direction corresponds to a thickness direction of the base member 30. At least a part of the connector 20 is electrically connected to the conductor pattern 10. That is, the interlayer connector 20 connects a first conductor pattern 10 to a second conductor pattern 10 located in a layer different from the first conductor pattern 10. Further, the circuit board 100 holds and supports a part of a terminal 200 inside of the base member 30. That is, a part of the terminal 200 is disposed in the base member 30. A tip end face 200a of the terminal 200 is electrically connected to the interlayer connector 20 located inside of the base member 30.

The circuit board 100 may further include an electronic component located inside of the base member 30, and the electronic component is electrically connected to the wiring portion. The electronic component may be a vertical metal-oxide-semiconductor field-effect transistor (MOSFET), insulated gate bipolar transistor (IGBT), or resistor, for example.

The insulation base member 30 is made of electrically insulating material, and supports the conductor pattern 10, the interlayer connector 20 and the terminal 200 at predetermined positions. Further, the base member 30 protects a connection between the terminal 200 and the wiring portion (interlayer connector 20), because the connection is sealed inside of the base member 30. If the circuit board 100 further includes the electronic component, the electronic component is held at a predetermined position of the base member 30, and the base member 30 seals and protects the electronic component.

The base member 30 is mainly made of resin, and the resin contains at least thermoplastic resin. The base member 30 is produced by layering resin films and by pressing and heating the layered resin films. The resin film contains thermoplastic resin, and the layered resin films are integrally bonded with each other by the pressing and heating process. The thermoplastic resin is softened when the base member 30 is produced in the pressing and heating process, and the softened resin is used as adhesive.

Therefore, a thermoplastic resin film may be located at least every other resin film when the resin films are layered with each other. The thermoplastic resin film is made of 30 wt % of polyetheretherketone (PEEK) and 70 wt % of polyetherimide (PEI), for example. The resin films constructing the base member 30 may be made of only thermoplastic resin films, or may contain a thermosetting resin film made of thermosetting resin such as polyimide (PI).

The thermoplastic resin film may contain inorganic material such as glass fiber or aramid fiber other than the thermoplastic resin, or may not contain the inorganic material other than the thermoplastic resin. Similarly, the thermosetting resin film may contain the inorganic material other than the thermosetting resin, or may not contain the inorganic material other than the thermosetting resin.

As shown in FIG. 2, the insulation base member 30 is constructed by layering a first thermoplastic resin film 31, a second thermoplastic resin film 32, a third thermoplastic resin film 33, a fourth thermoplastic resin film 34, and a fifth thermoplastic resin film 35 in this order. A first face 30b of the base member 30 is constructed by the first film 31, and a second face 30a of the base member 30 opposite from the first face 30b is constructed by the fifth film 35. That is, the insulation base member 30 is constructed by layering the thermoplastic resin films 31-35.

At least one of the resin films constructing the base member 30 has a through hole for accommodating the terminal 200. That is, the through hole is defined to pass through at least one of the resin films constructing the base member 30, and the through hole has a shape corresponding to an outer shape of the terminal 200 located inside of the circuit board 100. Specifically, a part of the resin film is cut and removed in accordance with the outer shape of the terminal 200. The outer shape of the terminal 200 is defined when the terminal 200 is assumed to be cut in a direction approximately perpendicular to a current flowing direction of the terminal 200. When the terminal 200 is arranged to extend in the thickness direction, the outer shape of the terminal 200 is defined by a cross-sectional shape of the terminal 200. The number of the resin films constructing the through hole for the terminal 200 is set in accordance with a length of the terminal 200 located inside of the circuit board 100 in the thickness direction. In the present embodiment, as shown in FIG. 2, for example, three through holes 331, 341, 351 are defined in the thermoplastic resin films 33, 34, 35, respectively.

The conductor pattern 10 is defined by patterning a conductive foil made of copper (Cu), for example. The interlayer connector 20 is defined by filling conductive paste into a via hole passing through the resin film in the thickness direction and by sintering conductive particles contained in the paste. The sintering is performed in the pressing and heating process, at the same time. That is, the interlayer connector 20 is made of a sintered member. The interlayer connector 20 is arranged inside of the insulation base member 30, and is made of Ag—Sn alloy, for example.

A plurality of the interlayer connectors 20 is defined in the circuit board 100. Some of the interlayer connectors 20 are electrically connected to the terminal 200. As shown in FIG. 1, the interlayer connector 20 is electrically connected with the tip end face 200a of the terminal 200 arranged in the insulation base member 30. The interlayer connector 20 and the terminal 200 are directly connected with each other. That is, the interlayer connector 20 and the terminal 200 are electrically and mechanically connected with each other.

Thus, the connection between the terminal 200 and the interlayer connector 20 are sealed with the thermoplastic resin, so that connection reliability can be raised.

A metal diffusion layer made of Cu—Sn alloy is generated in an interface between the conductor pattern 10 made of Cu and the interlayer connector 20 made of Ag—Sn alloy. Cu and Sn mutually diffuse with each other in the metal diffusion layer, thereby improving the connection reliability between the conductor pattern 10 and the interlayer connector 20.

The terminal 200 has a circular pillar shape or square pole shape, for example. The tip end face 200a of the terminal 200 is approximately flat. The terminal 200 is made of metal material such as iron-nickel alloy. However, the shape and the material of the terminal 200 are not limited to the above examples. A surface treatment may be performed to the tip end face 200a of the terminal 200 such as Nickel (Ni) plating in a manner that a metal bonding (metal diffusion connection) is generated between the face 200a of the terminal 200 and the interlayer connector 20.

As shown in FIG. 1, a part of the terminal 200 is arranged inside of the insulation base member 30 of the circuit board 100. The terminal 200 and the interlayer connector 20 are electrically connected with each other, and the thermoplastic resin contained in the base member 30 tightly contacts the terminal 200 located in the base member 30, so that a connection structure is defined. Specifically, entire surface of the terminal 200 located in the base member 30 except a part of the tip end face 200a connected with the interlayer connector 20 is tightly contact with the thermoplastic resin of the base member 30.

That is, the terminal 200 is partially buried inside of the base member 30 of the circuit board 100, and the other part of the terminal 200 protrudes outward from the second face 30a of the base member 30 in the thickness direction. The face 200a of the terminal 200 and the interlayer connector 20 are electrically connected with each other, and the thermoplastic resin of the base member 30 is tightly contact with the terminal 200 arranged in the base member 30.

Thus, the terminal 200 can be mechanically connected to the circuit board 100 without using a conventional elastic connector structure while the terminal 200 is electrically connected to the interlayer connector 20.

A method of connecting the terminal 200 to the circuit board 100 will be described with reference to FIG. 2. Reference numeral 20 of FIG. 2 indicates conductive paste corresponding to the interlayer connector 20 of FIG. 1.

The circuit board 100 is produced by pressing and heating a layered member. In a preparing of the layered member, the thermoplastic resin films 31-35 respectively made of 30 wt % of polyetheretherketone (PEEK) and 70 wt % of polyetherimide (PEI) are prepared. The thermoplastic resin film 31-35 does not contain inorganic material such as glass fiber or inorganic filler used for controlling a linear expansion coefficient.

In the preparing of the layered member, the conductor pattern 10 is arranged on the film 31-35, before a package integration is performed. The package integration is known as patterned prepreg lay up process (PALAP: registered trademark of DENSO CORPORATION), for example. Further, the conductive paste 20 is filled into the via hole of the film 31-35. The paste 20 becomes the interlayer connector 20 when the paste 20 is sintered. Furthermore, the through hole 331, 341, 351 is defined in the film 33, 34, 35 so as to have a shape corresponding to the terminal 200. Positions of the conductor patterns 10, the through holes 331, 341, 351 and the via holes filled with the paste 20 are set in accordance with a position of the terminal 200.

Especially, the position of the through hole 331, 341, 351 is set to correspond to the position of the terminal 200. That is, the through hole 331, 341, 351 is positioned to correspond to the terminal 200 in a state that the films 31-35 are layered with each other. Thus, the tip end face 200a of the terminal 200 located in the through hole 331, 341, 351 can oppose to the paste 20 to be electrically connected to the tip end face 200a in the thickness direction when a layering process is performed.

Basic construction and producing method of the circuit board 100 were already disclosed in previous patent applications by DENSO CORPORATION, and may be incorporated by reference into the present embodiment.

The conductor pattern 10 is defined by patterning the conductive foil on a surface of the resin film 31-35. All of the resin films 31-35 constructing the base member 30 may have the conductor pattern 10, or some of the resin films 31-35 constructing the base member 30 may not have the conductor pattern 10. The conductor pattern 10 may be arranged on only one face of the resin film, or may be arranged on both two faces of the resin film.

A method of producing the conductive paste 20 will be described. Ethyl cellulose resin or acrylic resin is added into conductive particles so as to have shape-keeping property. Further, organic solvent such as terpineol is added, and a mixing is performed in this state. The via hole passing through the resin film is defined using carbon dioxide laser, for example, and the conductive paste 20 is filled into the via hole by screen printing, for example. The via hole may be defined using the conductor pattern 10 as an undersurface, or may be defined at a position not having the conductor pattern 10.

If the via hole is defined on the conductor pattern 10, the paste 20 can stay in the via hole because the conductor pattern 10 functions as an undersurface. In contrast, in a case where the paste 20 is filled into a via hole not having the undersurface, conductive paste described in JP-A-2010-123760 may be used as the paste 20. Alternatively, the paste 20 may be filled into the via hole by referring to JP-A-2010-228104. JP-A-2010-123760 corresponds to Japanese Patent Application No. 2008-296074 filed by DENSO CORPORATION, and JP-A-2010-228104 corresponds to Japanese Patent Application No. 2009-75034 filed by DENSO CORPORATION, which are incorporated by reference.

Paraffin is added into the paste 20 as an example of resin having a low melting point and being solid at a room temperature. Paraffin decomposes or volatilizes at a temperature lower than a sintering temperature of the conductive particle. Paraffin is melted at a temperature lower than the sintering temperature and higher than the room temperature. Paraffin is melted into paste state by being heated when the paste 20 is filled into the via hole. When a cooling is performed, paraffin is hardened, so that the paste 20 becomes solid. Thus, the paste 20 can be held in the via hole. An end of the via hole is closed by a flat member, for example, when the paste 20 is filled into the via hole.

Next, a layering process to produce the layered member will be described. As shown in FIG. 2, the films 31-35 are layered in this order in the layering direction so as to define the layered member in a state that the terminal 200 is arranged in the through holes 331, 341, 351. At this time, the tip end face 200a of the terminal 200 opposes to the paste 20 to be electrically connected to the face 200a. The films 33-35 respectively having the through holes 331, 341, 351 are layered in this order. That is, the thermoplastic resin films 31-35 are layered in turn in a manner that the through hole 331, 341, 351 is exposed outside.

In a case where a thermosetting resin film is included in the layered member, the thermoplastic resin film is located at least every other resin film. That is, the thermosetting resin films and the thermoplastic resin films are alternately layered with each other.

The layered member is pressed in the layering direction while the layered member is heated using a vacuum heat pressing machine in the pressing and heating process. Specifically, the layered member is pressed in the layering direction while the films 31-35 and the terminal 200 are heated. Because the terminal 200 protrudes from the circuit board 100, a pressing mold 300 of the pressing machine has a through hole 310 through which the terminal 200 passes.

In the pressing and heating process, the thermoplastic resin is softened so that the films 31-35 are integrated with each other. Further, the terminal 200 located in the through hole 331-351 tightly contacts the thermoplastic resin, so that the terminal 200 is connected to the thermoplastic resin. Further, the conductive particles contained in the paste 20 are sintered, so that the wiring portion is defined by the sintered paste and the conductor pattern 10. Further, the tip end face 200a of the terminal 200 is electrically connected to the interlayer connector defined by the paste 20. That is, the softened thermoplastic resin is used as an adhesive.

In the pressing and heating process, a pressing temperature is set equal to or higher than a glass transition point of the thermoplastic resin and equal to or lower than a melting point of the thermoplastic resin. For example, the pressing temperature is 280° C.-330° C. Further, a pressure of 4-5 MPa, for example, is maintained during a predetermined time period such as 5 minutes or more. For example, the predetermined time period is 10 minutes. Thereby, the resin films 31-35 are integrated into the insulation base member 30, and the conductive particles of the paste 20 are sintered.

A state of connection between the resin films 31-35 in the pressing and heating process will be described. The layered films 31-35 are softened by the heating. At the same time, the layered member receives the pressure, so that the softened films 31-35 located adjacent with each other are tightly contact with each other. Thereby, the thermoplastic resin films are integrated into the insulation base member 30.

The film 32-35 located adjacent to the terminal 200 is softened by the heating, and becomes freely flowable by the pressing. The flowable resin contacts entire surface of the terminal 200 located in the through hole 331-351 except a part of the terminal 200 connected to the interlayer connector 20.

That is, before the pressing and heating process, a clearance is defined between the terminal 200 and the film 32-35. However, this clearance is filled with the thermoplastic resin of the film 32-35 after the pressing and heating process. Thus, the connection between the terminal 200 and the interlayer connector 20 is sealed with the thermoplastic resin. The terminal 200 located in the through hole 331-351 is sealed with the thermoplastic resin, so that the connection reliability is improved.

In a case where the thermosetting resin films and the thermoplastic resin films are alternately layered with each other, the thermoplastic resin film is softened by the heating. At this time, the softened resin receives the pressure, so that the softened resin tightly contacts the thermosetting resin film located adjacent to the softened resin. Thereby, the resin films (thermosetting resin films and thermoplastic resin films) are integrated into the insulation base member 30. In this case, a clearance defined between the terminal 200 and the thermosetting resin film is filled with the thermoplastic resin.

A state of connection among the terminal 200, the conductor pattern 10 and the interlayer connector 20 in the pressing and heating process will be described. In the heating, Sn contained in the conductive paste 20 is melted because Sn has a melting point of 232° C. The melted Sn diffuses into Ag particle contained in the conductive paste 20, thereby forming Ag—Sn alloy having a melting point of 480° C. Further, because the pressure is applied to the paste 20, the interlayer connector 20 is formed in the via hole. The interlayer connector 20 made of the alloy is integrated by the sintering.

Further, the melted Sn and Cu constructing the conductor pattern 10 diffuse with each other. Thereby, a metal diffusion layer (Cu—Sn alloy layer) is formed in the interface between the interlayer connector 20 and the conductor pattern 10. Furthermore, the melted Sn and Ni constructing the terminal 200 diffuse with each other. If a nickel plating is performed on a surface of the terminal 200, melted Sn and the plated Ni diffuse with each other. Thereby, a metal diffusion layer (Ni—Sn alloy layer) is formed in the interface between the interlayer connector 20 and the terminal 200.

According to the embodiment, as shown in FIG. 1, a part of the terminal 200 is arranged inside of the insulation base member 30 of the circuit board 100. The terminal 200 and the interlayer connector 20 are electrically connected with each other. The thermoplastic resin of the base member 30 tightly contacts the part of the terminal 200 arranged in the base member 30, so that the terminal 200 is connected to the base member 30 of the circuit board 100.

The terminal 200 and the interlayer connector 20 are electrically connected with each other, and the terminal 200 is tightly contact with the thermoplastic resin of the base member 30. Therefore, the terminal 200 is mechanically connected to the circuit board 100 without using a conventional elastic connector. That is, the terminal 200 is mechanically connected to the circuit board 100 while the terminal 200 is electrically connected to the interlayer connector 20. Therefore, the method of connecting the terminal 200 to the circuit board 100 can be simplified, and a time necessary for producing the circuit board 100 connected to the terminal 200 can be shortened.

Further, the connection between the terminal 200 and the interlayer connector 20 can be sealed with the thermoplastic resin, so that the connection reliability is improved.

The terminal 200 does not protrude from the first face 30b of the base member 30. Therefore, an electronic component can be flexibly mounted on the first face 30b of the base member 30, and a package density of the electronic component can be raised. Further, a mat wiring pattern can be easily arranged on the first face 30b of the base member 30.

### (First Modification)

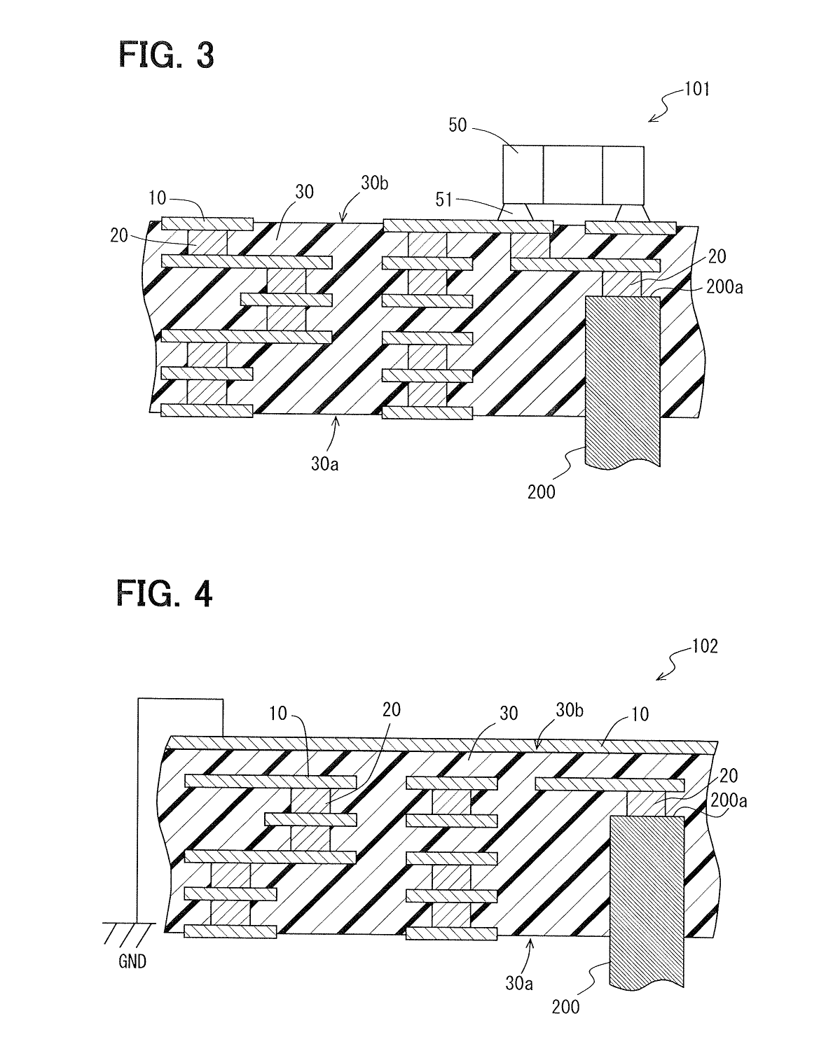

As shown in FIG. 3, a circuit board 101 includes an electronic component 50 such as noise filter element, and the electronic component 50 is mounted on a first face 30b of the circuit board 101. Other construction of the circuit board 101 is approximately similar to that of the circuit board 100 of the embodiment.

A point of a first modification different from the embodiment will be specifically described below, and detailed description of the similar part is omitted.

When the tip end face 200a of the terminal 200 is electrically connected to the interlayer connector 20, the terminal 200 is not exposed from the first face 30b of the circuit board 101. Therefore, the electronic component 50 can be mounted to the first face 30b. Designing of the electronic component 50 can be flexibly performed, and package density of the electronic component 50 can be raised.

The electronic component 50 is electrically connected to the conductor pattern 10 exposed from the insulation base member 30 through a connector 51.

### (Second Modification)

As shown in FIG. 4, a circuit board 102 includes a mat wiring pattern on the first face 30b. The mat wiring pattern is arranged in a wide area of the first face 30b, and is electrically maintained at a predetermined potential such as ground (GND). Other construction of the circuit board 102 is approximately similar to that of the circuit board 100 of the embodiment.

A point of a second modification different from the embodiment will be specifically described below, and detailed description of the similar part is omitted.

When the tip end face 200a of the terminal 200 is electrically connected to the interlayer connector 20, the terminal 200 is not exposed from the first face 30b of the circuit board 101. Therefore, the mat wiring pattern is easily arranged on the first face 30b. Further, shielding property can be raised because the mat wiring pattern is electrically maintained at a predetermined potential (GND).

### (Third Modification)

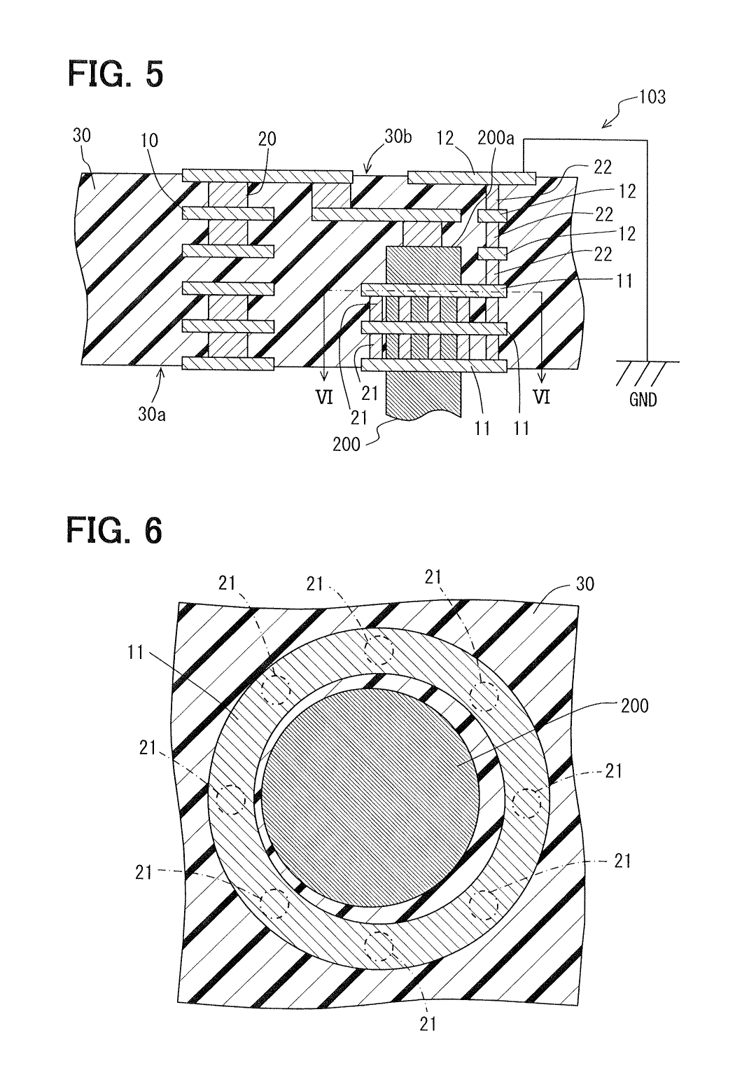

As shown in FIGS. 5 and 6, a circuit board 103 includes a shielding portion to surround at least a side wall of the terminal 200 located in the base member 30. The shielding portion is arranged inside of the base member 30, and is electrically maintained at a predetermined potential such as ground (GND). The shielding portion is located around the terminal 200, and is insulated from the terminal 200 by the insulation base member 30. Other construction of the circuit board 103 is approximately similar to that of the circuit board 100 of the embodiment.

A point of a third modification different from the embodiment will be specifically described below, and detailed description of the similar part is omitted.

The shielding portion is constructed by a shielding conductor pattern 11, a shielding interlayer connector 21, a ground conductor pattern 12 and a ground interlayer connector 22. For example, plural such as three of the shielding patterns 11 are layered. Plural such as eight of the shielding connectors 21 connect the shielding patterns 11 located adjacent with each other, so that the circuit board 103 has sixteen of the shielding connectors 21 as a total. Plural such as three of the ground patterns 12 are layered, and the ground pattern 12 connects the shielding pattern 11 to the ground. The ground connector 22 connects the shielding pattern 11 to the ground pattern 12, and connects the ground patterns 12 with each other. The shielding pattern 11 and the shielding connector 21 are connected to the ground pattern 12 fixed at the ground potential through the ground connector 22.

As shown in FIG. 6, the shielding pattern 11 has a ring shape with a predetermined width in a plane direction approximately perpendicular to the layering direction. The terminal 200 is located inside of the ring shape through the insulation base member 30. The shielding pattern 11 is positioned to surround the side wall of the terminal 200. The shape of the shielding pattern 11 is not limited to this example.

The shielding connectors 21 are arranged in a circumference direction with a uniform interval, and are positioned to surround the side wall of the terminal 200 through the base member 30. The position of the shielding connector 21 is not limited to this example.

The conductor pattern 11, 12 and the interlayer connector 21, 22 are produced by using a similar material and method as the embodiment.

The layer number of the conductor patterns 11, 12 is not limited to the above example. The number of the interlayer connectors 21, 22 is not limited to the above example. As the number of the shielding connectors 21 arranged between the shielding patterns 11 is increased, the shielding property can be raised.

Therefore, noise generated from the terminal 200 can be restricted from being transmitted to the circuit board 103. Further, because the shielding portion is constructed by the conductor pattern 11, 12 and the interlayer connector 21, 22, which are similar to the conductor pattern 10 and the interlayer connector 20, the producing method of the circuit board 103 can be simplified.

### (Fourth Modification)

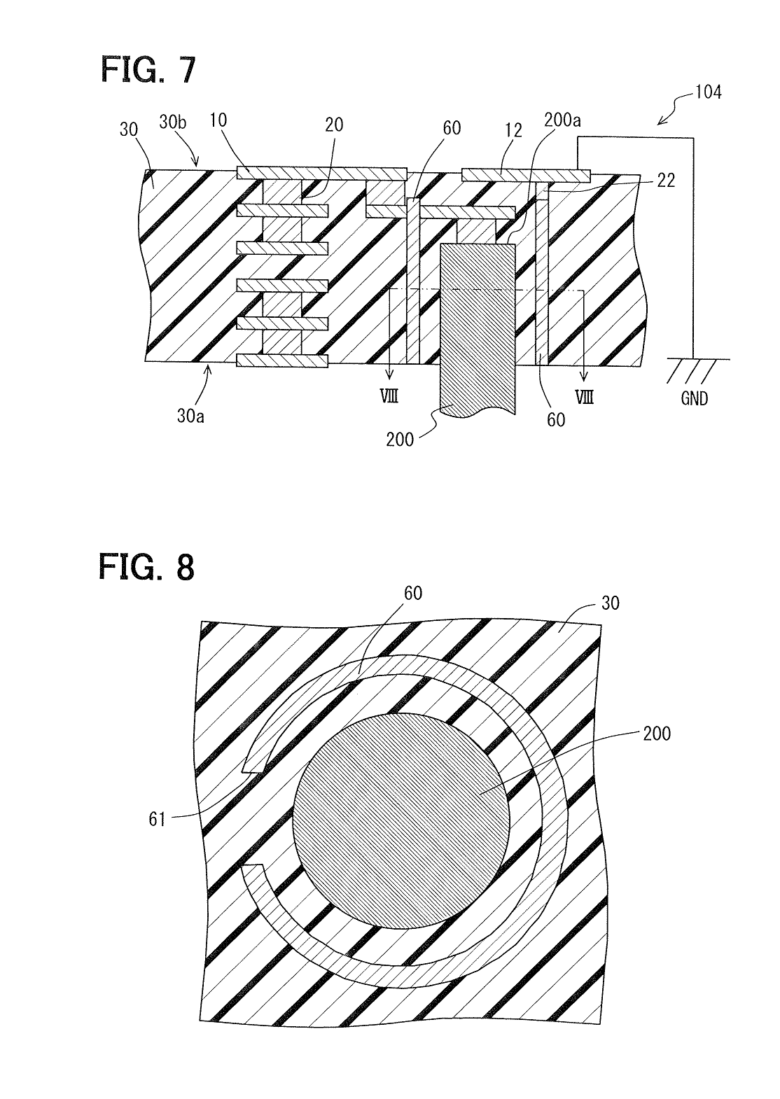

As shown in FIGS. 7 and 8, a circuit board 104 includes a shielding portion to surround at least a side wall of the terminal 200 located in the base member 30. The shielding portion has an approximately cylindrical part 60, and is electrically maintained at a predetermined potential such as ground (GND). The shielding portion is insulated from the terminal 200 by the insulation base member 30. Other construction of the circuit board 104 is approximately similar to that of the circuit board 103 of the third modification.

A point of a fourth modification different from the third modification or the embodiment will be specifically described below, and detailed description of the similar part is omitted.

The shielding portion further includes a ground conductor pattern 12 and a ground interlayer connector 22 other than the cylindrical part 60. The ground pattern 12 connects the cylindrical part 60 to the ground. The ground connector 22 connects the cylindrical part 60 to the ground pattern 12. As shown in FIG. 7, the cylindrical part 60 is connected to the ground pattern 12 fixed at the ground potential through the ground connector 22.

The terminal 200 is positioned inside of the cylindrical part 60 through the base member 30. The cylindrical part 60 is located to surround the side wall of the terminal 200. That is, the cylindrical part 60 is produced by being arranged in a through hole passing through a thickness direction of the base member 30. The thickness direction corresponds to a longitudinal direction of the cylindrical part 60 or a current passing direction of the terminal 200. The terminal 200 is also arranged in the through hole, and a clearance between the terminal 200 and the cylindrical part 60 is filled with the base member 30.

As shown in FIG. 8, the cylindrical part 60 has an opening 61 continuously extending in the thickness direction. That is, the cylindrical part 60 continuously has a C-shape cross-section.

Due to the opening 61, the interlayer connector 20 connected to the face 200a of the terminal 200 can be flexibly connected to other wiring. That is, wiring can be easily arranged in the circuit board 104.

The through hole is necessary to be defined in the resin films to be formed into the base member 30 when the circuit board 104 is produced. Due to the opening 61, a resin film located between the cylindrical part 60 and the terminal 200 can be integrated with a resin film located outside of the cylindrical part 60.

The cylindrical part 60 may not have the opening 61. In this case, the interlayer connector 20 connected to the face 200a of the terminal 200 is connected to the other wiring through a space defined between the first face 30b of the base member 30 and a tip end of the cylindrical part 60 in the thickness direction of the base member 30. The insulation base member 30 located between the terminal 200 and the cylindrical part 60 is produced by arranging resin films respectively having through holes for the terminal 200 in the layering process.

Therefore, noise generated from the terminal 200 can be restricted from being transmitted to the circuit board 104. Further, the shielding property can be raised, compared with the third modification.

### (Fifth Modification)

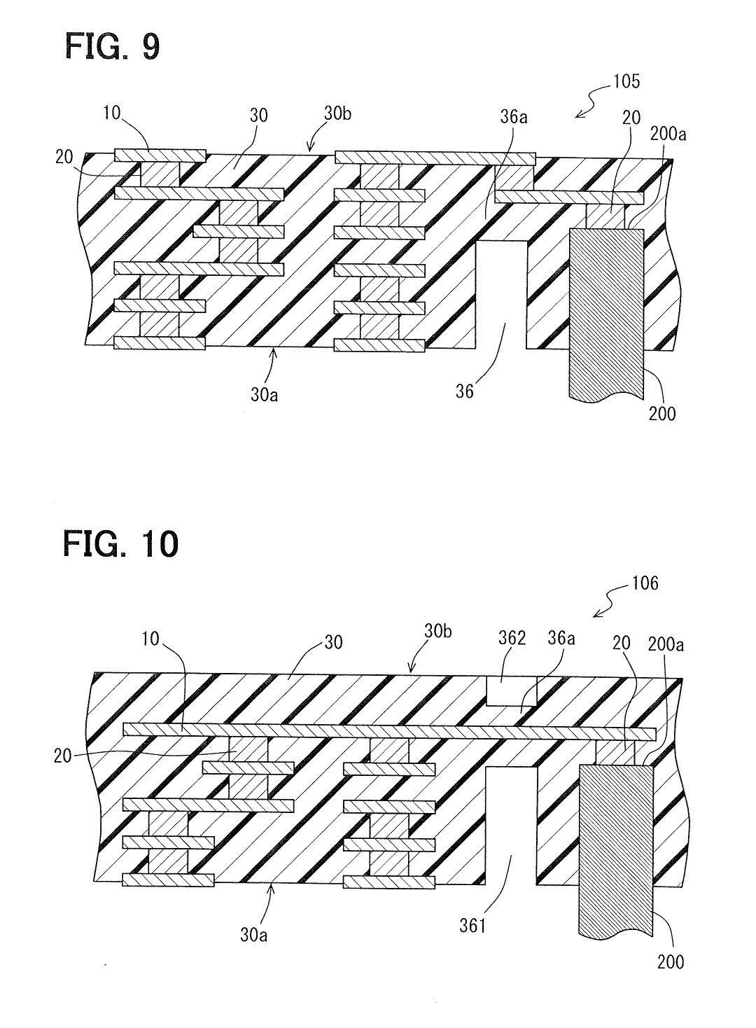

As shown in FIG. 9, the insulation base member 30 of the circuit board 105 has a membrane part 36a adjacent to the terminal 200. The membrane part 36a is constructed by defining a recess 36 recessed from the second face 30a of the base member 30 in the thickness direction. Other construction of the circuit board 105 is approximately similar to that of the circuit board 100 of the embodiment.

A point of a fifth modification different from the embodiment will be specifically described below, and detailed description of the similar part is omitted.

In the above embodiment, if the circuit board 100 having the terminal 200 is mounted to an object, position deviation may be generated between the circuit board 100 and the terminal 200 in the object. Further, position deviation may be generated for the terminal 200 in the circuit board 100. In these cases, a stress may be applied to the circuit board 100 by the position deviation. Further, a stress may be applied to the circuit board 100 by a difference of thermal expansion coefficient between material constructing the base member 30 and material constructing the terminal 200.

In contrast, according to the fifth modification, as shown in FIG. 9, the membrane part 36a is defined adjacent to the terminal 200 by the recess 36 of the circuit board 105. In this example, the recess 36 is defined only on the second face 30a from which the terminal 200 protrudes. Further, the recess 36 may be located between the terminal 200 and the wiring portion adjacent to the terminal 200 in the plane direction.

The membrane part 36a may continuously extend between side walls of the circuit boar 105 (insulation base member 30) in the plane direction approximately perpendicular to the thickness direction. The membrane part 36a may linearly extend between the side walls opposing to each other. Alternatively, the membrane part 36a may continuously extend between the side walls not opposing to each other. In this case, a bent part is defined in the membrane part 36a, and the bent part is bent in the plane direction.

The membrane part 36a is defined before the pressing and heating process by removing a part of the layered resin films from the second face 30a. The number of the resin films having the removing is determined based on a length of the recess 36 in the thickness direction. The removed part has a position and a shape corresponding to the recess 36. If the length of the recess 36 is shorter than a thickness of a single resin film, the recess 36 is produced on a surface of the base member 30 without defining the through hole in the resin film. Alternatively, the recess 36 may be defined after the pressing and heating process. Thus, the stress applied to the circuit board 105 can be eased by the membrane part 36a.

### (Sixth Modification)

As shown in FIG. 10, the circuit board 106 has a membrane part 36a produced by defining a first recess 361 and a second recess 362. The first recess 361 is defined on the second face 30a, and is recessed in the thickness direction. The second recess 362 is defined on the first face 30b, and is recessed in the thickness direction. The membrane part 36a is located adjacent to the terminal 200. A position of the first recess 361 corresponds to that of the second recess 362 in the thickness direction. Thus, the stress applied to the circuit board 106 can be eased by the membrane part 36a.

Other construction of the circuit board 106 is approximately similar to that of the circuit board 105 of the fifth modification, so that detailed description of the similar part is omitted.

### (Seventh Modification)

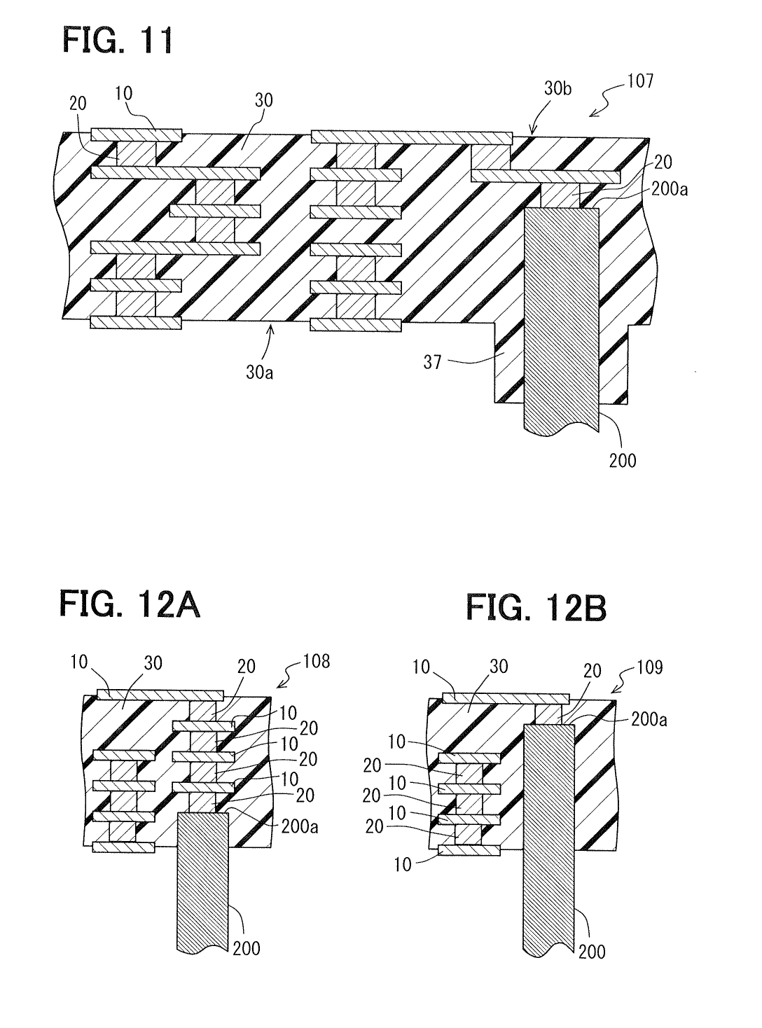

As shown in FIG. 11, the circuit board 107 has a first section in which the terminal 200 is arranged, and a thickness of the first section is set larger than that of the other section. That is, the base member 30 has a protrusion 37 protruding from the second face 30a in the thickness direction, and the terminal 200 is located in the protrusion 37. Other construction of the circuit board 107 is approximately similar to that of the circuit board 100 of the embodiment.

A point of a seventh modification different from the embodiment will be specifically described below, and detailed description of the similar part is omitted.

The protrusion 37 is located on the second face 30a from which the terminal 200 protrudes. A cross-sectional area of the protrusion 37 is larger than that of the terminal 200, when a cross-section is defined in a direction approximately perpendicular to the current flowing direction of the terminal 200.

A cross-sectional shape of the protrusion 37 is set approximately the same as the terminal 200, but is not limited to be the same.

The terminal 200 located in the protrusion 37 is tightly contact with the thermoplastic resin of the base member 30, so that the terminal 200 is mechanically connected to the protrusion 37.

The protrusion 37 is defined by removing a part of the layered resin films from the second face 30a before the pressing and heating process. The number of the resin films having the removing is determined based on a length of the protrusion 37 in the thickness direction.

Thus, an area between which the terminal 200 and the thermoplastic resin are tightly contact with each other can be increased in the thickness direction, so that the terminal 200 can be restricted from separating from the base member 30.

### (Eighth Modification)

When the tip end face 200a of the terminal 200 is electrically connected to the interlayer connector 20 in a circuit board 108, as shown in FIG. 12A, plural such as four of the conductor patterns 10 are layered above the terminal 200 in the thickness direction. Alternatively, as shown in FIG. 12B, a single conductor pattern 10 is arranged above the terminal 200 in the thickness direction in a circuit board 109. In this case, in the preparing of the layered member, a through hole is defined in a predetermined number of the resin films based on a length of the terminal 200 located inside of the base member 30.

Therefore, the length of the terminal 200 located in the base member 30 can be flexibly changed. Other construction of the circuit board 108, 109 is approximately similar to that of the circuit board 100 of the embodiment, and detailed description of the similar part is omitted.

### (Ninth Modification)

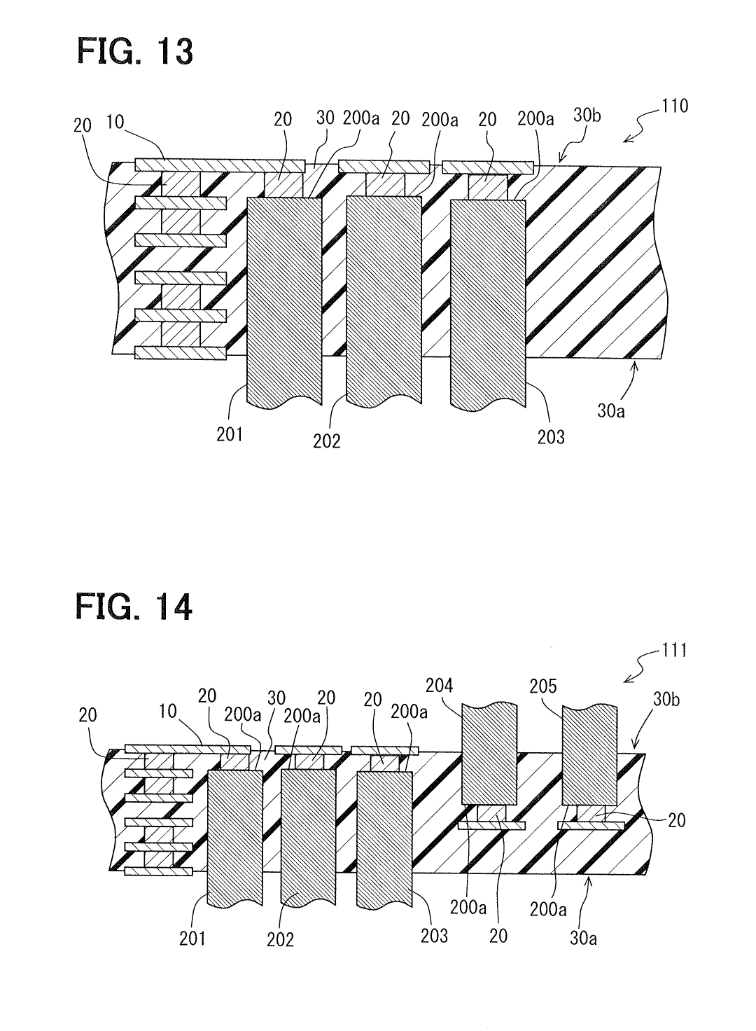

As shown in FIG. 13, plural terminals 201, 202, 203 are connected to a circuit board 110. The terminal 201, 202, 203 protrudes from the second face 30a of the base member 30. In this case, in the preparing of the layered member, plural through holes are defined in a predetermined number of the resin films based on the number of the terminals located inside of the circuit board 110.

Other construction of the circuit board 110 is approximately similar to that of the circuit board 100 of the embodiment, and detailed description of the similar part is omitted.

### (Tenth Modification)

As shown in FIG. 14, plural terminals 201, 202, 203 protruding from the second face 30a of the base member 30 are connected to a circuit board 111. Further, plural terminals 204, 205 protruding from the first face 30b of the base member 30 are connected to the circuit board 111. In this case, in the preparing of the layered member, plural through holes are defined in a predetermined number of the resin films based on the number of the terminals located inside of the circuit board 111.

Other construction of the circuit board 111 is approximately similar to that of the circuit board 100 of the embodiment, and detailed description of the similar part is omitted.

### (Eleventh Modification)

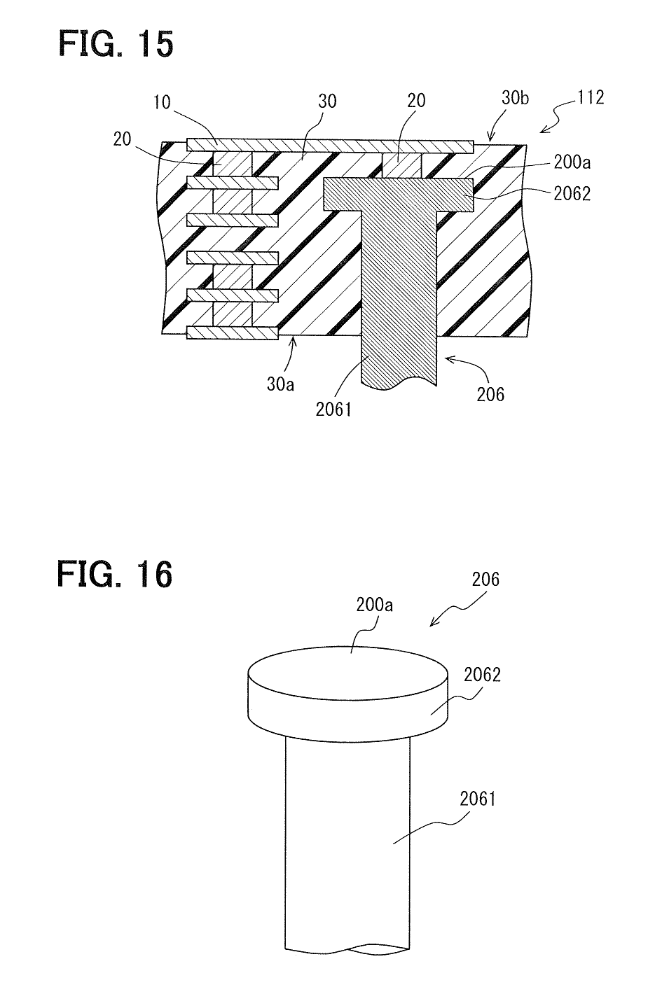

As shown in FIGS. 15 and 16, a terminal 206 is connected to a circuit board 112, and has a flange 2062 located inside of the base member 30. Other construction of the circuit board 112 is approximately similar to that of the circuit board 100 of the embodiment, and detailed description of the similar part is omitted.

The terminal 206 has a vertical part 2061 other than the flange 2062. The vertical part 2061 extends in an axis direction of the terminal 206, and the flange 2062 extends from an end portion of the vertical part 2061 in a direction approximately perpendicular to the vertical part 2061. That is, the terminal 206 has a nail shape. Both of the vertical part 2061 and the flange 2062 have column shape. A diameter of the flange 2062 is larger than that of the vertical part 2061. The flange 2062 has a flat face 200a that is electrically connected to the interlayer connector 20.

The flange 2062 is not limited to extend from the end portion of the vertical part 2061. If the flange 2062 extends from other position of the vertical part 2061, a tip end face of the vertical part 2061 corresponds to the flat face 200a electrically connected to the interlayer connector 20.

As shown in FIG. 15, a part of the vertical part 2061 and the flange 2062 are located in the base member 30. The terminal 206 is restricted from separating from the base member 30 because the flange 2062 is located in the base member 30.

### (Twelfth Modification)

As shown in FIG. 17, the terminal 206 has a vertical part 2061 extending in the axis direction of the terminal 206 and a flange 2062 extending from an end portion of the vertical part 2061 in a direction approximately perpendicular to the vertical part 2061. Each of the vertical part 2061 and the flange 2062 has a rectangular prism shape. The terminal 206 is restricted from separating from the base member 30 because the flange 2062 is located in the base member 30.

The shape of the terminal 206 of the twelfth modification is different from that of the eleventh modification. Other construction of the twelfth modification is approximately similar to that of the eleventh modification, and detailed description of the similar part is omitted.

### (Thirteenth Modification)

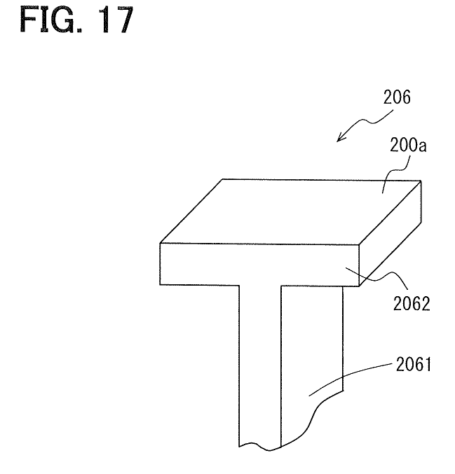

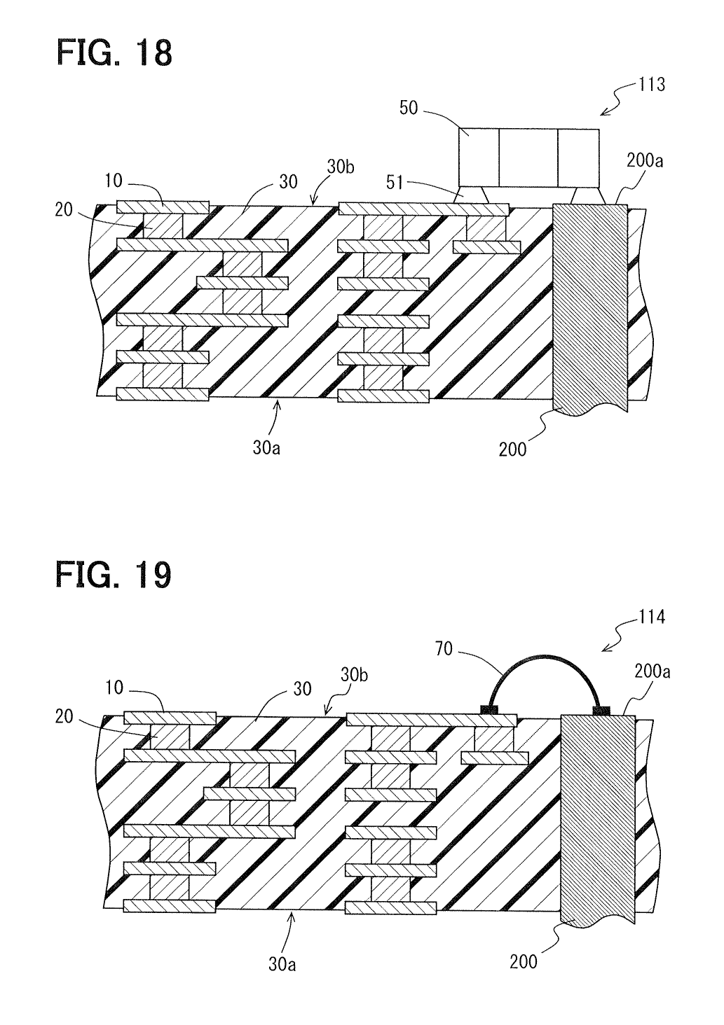

As shown in FIG. 18, a circuit board 113 includes a connecting portion that connects the terminal 200 to the wiring portion. The connecting portion has a noise filter element 50 corresponding to an electronic component and a connector 51 connecting the filter element 50 to the conductor pattern 10. The end face 200a of the terminal 200 is exposed from the base member 30, and is electrically connected to the conductor pattern 10 exposed from the base member 30 through the connecting portion. Thereby, a distance between the terminal 200 and the filter element 50 can be made short.

Other construction of the circuit board 113 is approximately similar to that of the circuit board 100 of the embodiment, and detailed description of the similar part is omitted.

### (Fourteenth Modification)

As shown in FIG. 19, a circuit board 114 includes a bonding wire 70 that connects the terminal 200 to the wiring portion. The bonding wire 70 corresponds to a connecting portion. The end face 200a of the terminal 200 is exposed from the base member 30, and is electrically connected to the conductor pattern 10 exposed from the base member 30 through the bonding wire 70. Thereby, the face 200a of the terminal 200 can be connected to the conductor pattern 10 while the face 200a is exposed from the base member 30.

Other construction of the circuit board 114 is approximately similar to that of the circuit board 100 of the embodiment, and detailed description of the similar part is omitted.

### (Fifteenth Modification)

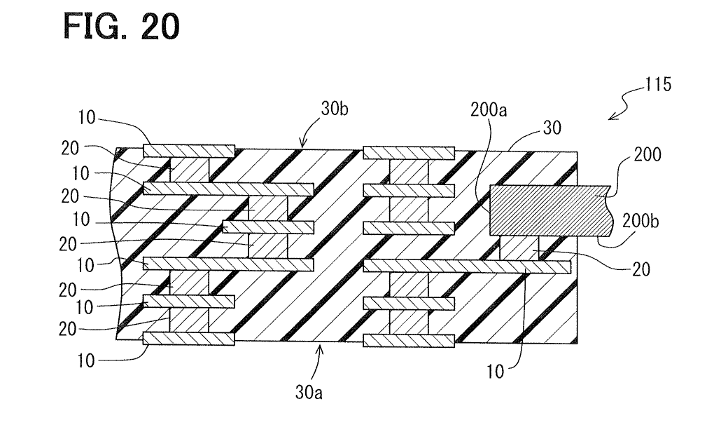

As shown in FIG. 20, the terminal 200 protrudes from a side wall of a circuit board 115. In this case, a part of a side wall 200b of the terminal 200 located in the base member 30 is electrically connected to the interlayer connector 20.

The embodiment and the first to fifteenth modifications may be combined with each other.

### (Sixteenth Modification)

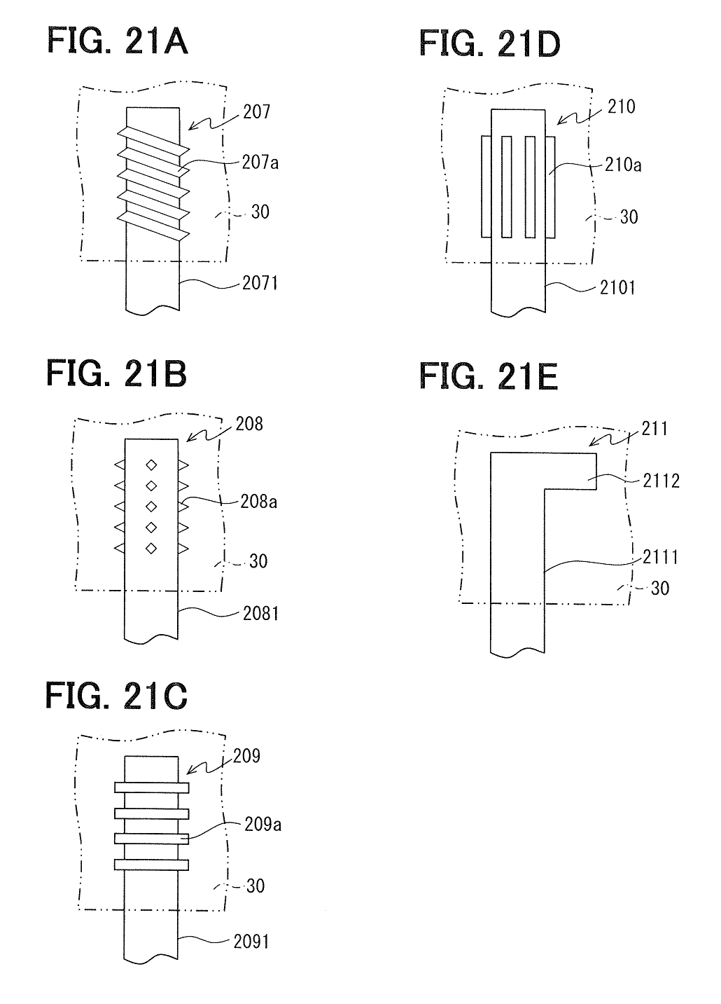

As shown in FIGS. 21A-21E, the terminal 207-211 has a vertical part 2071-2111 extending in an axis direction of the terminal 207-211 and a protrusion 207a-210a, 2112 protruding from a side wall of the vertical part 2071-2111. The protrusion 207a-210a, 2112 is located inside of the base member 30. Other construction is approximately similar to that of the circuit board 100 of the embodiment, and detailed description of the similar part is omitted.

As shown in FIG. 21A, the terminal 207 has the vertical part 2071 and the protrusion 207a protruding from a side wall of the vertical part 2071. The protrusion 207a has a helical shape. A periphery of the protrusion 207a may be defined as a recessed part recessed from the protrusion 207a.

A part of the vertical part 2071 and the protrusion 207a are located in the base member 30.

Therefore, a contact area between the terminal 207 and the base member 30 can be increased, so that the terminal 207 is restricted from separating from the base member 30.

Alternatively, if a helical recessed part is defined around the side wall of the terminal 207, a periphery of the helical recessed part corresponds to a protrusion.

As shown in FIG. 21B, the terminal 208 has the vertical part 2081 and a plurality of the protrusions 208a. The protrusion 208a has a pyramid shape. A periphery of the protrusion 208a may be defined as a recessed part recessed from the protrusion 208a.

Alternatively, the protrusion 208a may have a triangular pyramid shape, quadrangular prism shape or triangular prism shape, for example.

A part of the vertical part 2081 and the protrusion 208a are located in the base member 30.

Therefore, a contact area between the terminal 208 and the base member 30 can be increased, so that the terminal 208 is restricted from separating from the base member 30.

Alternatively, a recessed part having a pyramid shape, triangular pyramid shape, quadrangular prism shape or triangular prism shape may be defined on the side wall of the terminal 208. In this case, a periphery of the recessed part corresponds to a protrusion.

As shown in FIG. 21C, the terminal 209 has the vertical part 2091 and a plurality of the protrusions 209a. The protrusion 209a has a flange (ring) shape having the same axis as the vertical part 2091. A periphery of the protrusion 209a may be defined as a recessed part recessed from the protrusion 209a.

A part of the vertical part 2091 and the protrusion 209a are located in the base member 30.

Therefore, a contact area between the terminal 209 and the base member 30 can be increased, so that the terminal 209 is restricted from separating from the base member 30.

Alternatively, a recessed part having a ring shape may be defined on the side wall of the terminal 209. In this case, a periphery of the recessed part corresponds to a protrusion.

As shown in FIG. 21D, the terminal 210 has the vertical part 2101 and a plurality of the protrusions 210a. The protrusion 210a has a linear shape extending in the axis direction of the terminal 210. In other words, the protrusion 210a has a stripe shape. A periphery of the protrusion 210a may be defined as recessed part recessed from the protrusion 210a.

A part of the vertical part 2101 and the protrusion 210a are located in the base member 30.

Therefore, a contact area between the terminal 210 and the base member 30 can be increased, so that the terminal 210 is restricted from separating from the base member 30.

Alternatively, a recessed part having the linear shape may be defined around the side wall of the terminal 210. In this case, a periphery of the recessed part corresponds to a protrusion.

As shown in FIG. 21E, the terminal 211 has the vertical part 2111 and the protrusion 2112. The protrusion 2112 protrudes from a tip end of the terminal 211 in a direction approximately perpendicular to the vertical part 2111, but is not limited to this example. The protrusion 2112 may protrude in a direction inclined to the perpendicular direction.

A part of the vertical part 2111 and the protrusion 2112 are located in the base member 30.

Therefore, a contact area between the terminal 211 and the base member 30 can be increased, so that the terminal 211 is restricted from separating from the base member 30.

In other words, the terminal 207-211 has the vertical part 2071-2111 and an asperity defined on a side wall of the vertical part 2071-2111.

The terminal 207-211 may be applied into the embodiment and the first to fifteenth modifications. For example, the terminal 207-211 of the sixteenth modification is combined with the terminal 206 of the eleventh or twelfth modification in a following eighteenth modification.

### (Seventeenth Modification)

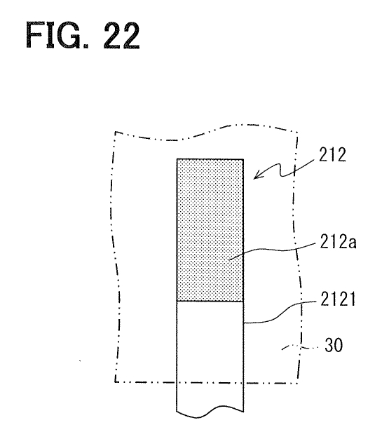

As shown in FIG. 22, a terminal 212 has a vertical part 2121 and a rough part 212a defined on a side wall of the vertical part 2121. The rough part 212a is arranged inside of the base member 30. Other construction is approximately similar to that of the circuit board 100 of the embodiment, and detailed description of the similar part is omitted.

A part of the vertical part 2121 and the rough part 212a are located in the base member 30. The rough part 212a is defined by roughening the side wall of the vertical part 2121 using a known plating treatment or sandblast.

The rough part 212a corresponds to asperities, so that the terminal 212 has the vertical part 2121 and the asperities defined on the side wall of the vertical part 2121.

A part of the vertical part 2121 and the rough part 212a are located in the base member 30.

Therefore, a contact area between the terminal 212 and the base member 30 can be increased, so that the terminal 212 is restricted from separating from the base member 30.

The rough part 212a may be defined in the terminal 206-211 of the eleventh or sixteenth modification. For example, a roughening treatment is performed for the flange 2062 or the protrusion 207a-210a, 2112 of the terminal 206-211. Thereby, the terminal 206-211 is further restricted from separating from the base member 30.

The terminal 212 of the seventeenth modification may be applied into the embodiment and the first to fifteenth modifications. For example, the terminal 212 of the seventeenth modification is combined with the terminal 206 of the eleventh or twelfth modification in a following eighteenth modification.

### (Eighteenth Modification)

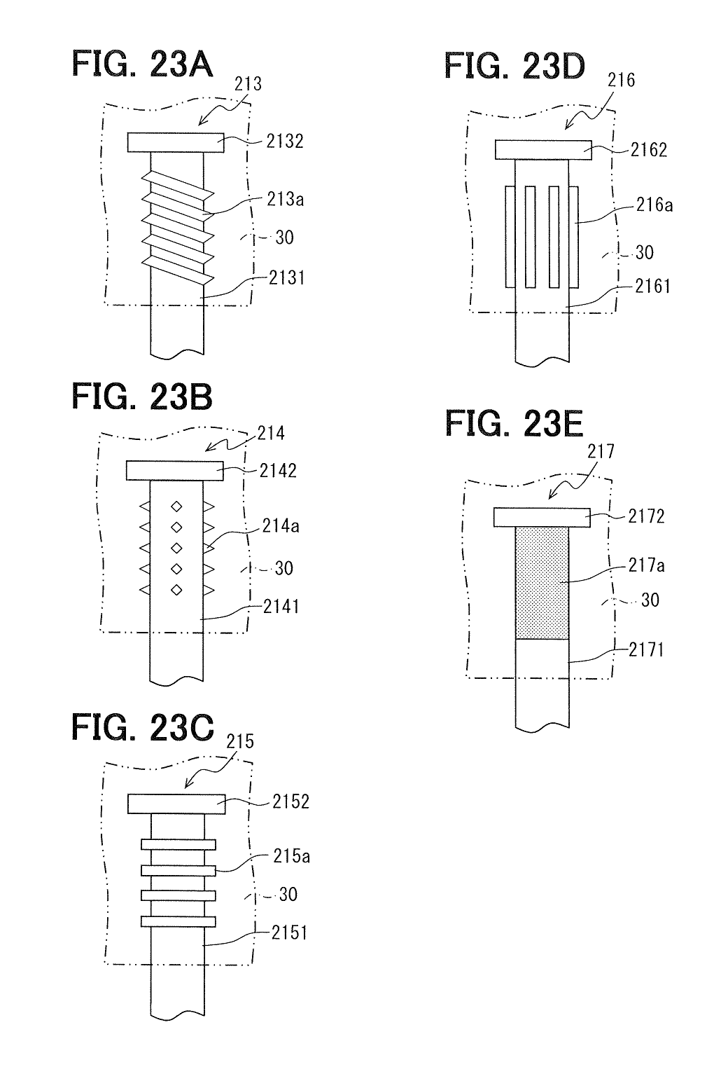

The flange 2062 of the eleventh modification and the protrusion 207a-210a of the sixteenth modification are combined in FIGS. 23A-23D. The flange 2062 of the eleventh modification and the rough part 212a of the seventeenth modification are combined in FIG. 23E. Other construction is approximately similar to that of the embodiment or the above modification, and detailed description of the similar part is omitted.

As shown in FIG. 23A, the terminal 213 has a vertical part 2131 extending in an axis direction of the terminal 213, a helical protrusion 213a protruding from a side wall of the vertical part 2131, and a flange 2132 extending from an end portion of the vertical part 2131 in a direction approximately perpendicular to the vertical part 2131.

A part of the vertical part 2131, the flange 2132 and the protrusion 213a are located in the base member 30, so that the terminal 213 is further restricted from separating from the base member 30.

As shown in FIG. 23B, the terminal 214 has a vertical part 2141 extending in an axis direction of the terminal 214, a protrusion 214a protruding from a side wall of the vertical part 2141, and a flange 2142 extending from an end portion of the vertical part 2141 in a direction approximately perpendicular to the vertical part 2141. The protrusion 214a has a pyramid shape, triangular pyramid shape, quadrangular prism shape or triangular prism shape, for example.

A part of the vertical part 2141, the flange 2142 and the protrusion 214a are located in the base member 30, so that the terminal 214 is further restricted from separating from the base member 30.

As shown in FIG. 23C, the terminal 215 has a vertical part 2151 extending in an axis direction of the terminal 215, a ring-shaped protrusion 215a protruding from a side wall of the vertical part 2151, and a flange 2152 extending from an end portion of the vertical part 2151 in a direction approximately perpendicular to the vertical part 2151.

A part of the vertical part 2151, the flange 2152 and the protrusion 215a are located in the base member 30, so that the terminal 215 is further restricted from separating from the base member 30.

As shown in FIG. 23D, the terminal 216 has a vertical part 2161 extending in an axis direction of the terminal 216, a linear protrusion 216a protruding from a side wall of the vertical part 2161, and a flange 2162 extending from an end portion of the vertical part 2161 in a direction approximately perpendicular to the vertical part 2161. The linear protrusion 216a extends in the axis direction of the terminal 216.

A part of the vertical part 2161, the flange 2162 and the protrusion 216a are located in the base member 30, so that the terminal 216 is further restricted from separating from the base member 30.

As shown in FIG. 23E, the terminal 217 has a vertical part 2171 extending in an axis direction of the terminal 217, a rough part 217a defined on a side wall of the vertical part 2171, and a flange 2172 extending from an end portion of the vertical part 2171 in a direction approximately perpendicular to the vertical part 2171.

A part of the vertical part 2171, the flange 2172 and the rough part 217a are located in the base member 30, so that the terminal 217 is further restricted from separating from the base member 30.

In FIG. 21E, the protrusion 2112 protrudes from the tip end of the terminal 211. In this case, the terminal 211 cannot have a flange at the tip end of the terminal 211. However, a flange may be arranged at the tip end of the terminal 211 if the protrusion 2112 protrudes from a position other than the tip end.

The flange 2132-2172 may extend from the side wall of the vertical part 2131-2171 in a direction inclined to the perpendicular direction.

The terminal 206 of the twelfth modification may be combined with the terminal 207-212 of the sixteenth or seventeenth modification.

The terminal 213-217 of the eighteenth modification may be combined with the embodiment, the first to tenth modifications, and the thirteenth to fifteenth modifications.

Such changes and modifications are to be understood as being within the scope of the present invention as defined by the appended claims.

What is claimed is:

1. A connection structure comprising:
a circuit board including
an insulation base member containing thermoplastic resin, and
a wiring portion arranged inside of the insulation base member, the wiring portion having a conductor pattern and an interlayer connector, at least a part of the interlayer connector being electrically connected to the conductor pattern; and
a terminal made of metal material, wherein
the terminal is electrically connected to a part of the wiring portion,
the terminal has a first section arranged inside of the insulation base member, and
the first section of the terminal is tightly contact with the thermoplastic resin of the insulation base member, such that the terminal is connected to the circuit board.

2. The connection structure according to claim 1, wherein
the terminal has a connection connected to the wiring portion, and
the connection is located inside of the insulation base member.

3. The connection structure according to claim 1, wherein
the insulation base member has a membrane part having a membrane shape,
the membrane part is constructed by defining a recess on a surface of the insulation base member, and
the membrane part is located adjacent to the terminal.

4. The connection structure according to claim 1, wherein
the terminal has a vertical part extending in an axis direction of the terminal, and a protrusion protruding from a side wall of the vertical part, and
a part of the vertical part and the protrusion are positioned inside of the insulation base member.

5. The connection structure according to claim 4, wherein
the protrusion includes a flange extending in a direction approximately perpendicular to the vertical part.

6. The connection structure according to claim 4, wherein
the protrusion has a helical part having a helical shape.

7. The connection structure according to claim 4, wherein
the protrusion is one of a plurality of protrusions.

8. The connection structure according to claim 1, wherein
the terminal has a vertical part extending in an axis direction of the terminal, and a rough part defined on a side wall of the vertical part, and
a part of the vertical part and the rough part are positioned inside of the insulation base member.

9. The connection structure according to claim 8, wherein
the rough part is made of a plating film having a rough face.

10. The connection structure according to claim 1, further comprising:
a shielding portion disposed inside of the insulation base member, wherein
the shielding portion surrounds at least a side wall of the terminal located inside of the insulation base member, and
the shielding portion is electrically fixed at a predetermined potential.

11. The connection structure according to claim 10, wherein
the shielding portion is constructed by a conductor pattern and an interlayer connector.

12. The connection structure according to claim 10, wherein
the shielding portion is made of metal material, and has a cylindrical shape.

13. The connection structure according to claim 1, wherein
the insulation base member has a section in which the terminal is arranged, and
the section has a thickness larger than that of the other section in a thickness direction of the circuit board.

14. The connection structure according to claim 1, further comprising:
a connecting portion that electrically connects a part of the terminal exposed from the insulation base member to the wiring portion, wherein
the connecting portion is a noise filter element.

15. The connection structure according to claim 1, further comprising:
a connecting portion that electrically connects a part of the terminal exposed from the insulation base member to the wiring portion, wherein
the connecting portion is a bonding wire.
